(19) United States
(12) Patent Application Publication
(10) Pub. No.: US 2007/0197021 A1
(43) Pub. Date: Aug. 23, 2007

(54) Semiconductor device including spacer with nitride/nitride/oxide structure and method for fabricating the same

(75) Inventors: Ki-Won Nam, Kyoungki-do (KR); Ky-Hyun Han, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/595,308

(22) Filed: Nov. 9, 2006

(30) Foreign Application Priority Data
Feb. 21, 2006 (KR) 2006-0016721
Oct. 13, 2006 (KR) 2006-0099886

(51) Int. Cl. H01L 21/4763

(52) U.S. Cl. 438/622

(57) ABSTRACT

A method for fabricating a semiconductor device includes: forming a plurality of bit lines; forming an inter-layer insulation layer over the bit lines; etching the inter-layer insulation layer to form a storage node contact hole between the bit lines; forming spacers in a dual structure with different dielectric constants over sidewalls of the storage node contact hole; and forming a storage node contact plug filling the storage node contact hole.

### FIELD OF THE INVENTION

The present invention relates to a method for fabricating a semiconductor device; and more particularly, to a method for fabricating a semiconductor device capable of reducing parasitic capacitance.

### DESCRIPTION OF RELATED ARTS

As the scale of a semiconductor device has been more highly integrated, a distance between lines has been decreased, and a thickness of an insulation layer interposed between a word line and a bit line or between capacitors has become thinner. Accordingly, undesirable parasitic capacitance is increased, thereby degrading a property of the device.

In case of simply increasing a thickness of an inter-layer insulation layer to reduce the parasitic capacitance, a gap-fill margin of the inter-layer insulation layer resulting from the reduction in the space between the lines may be decreased.

In case of using a semiconductor device with a size of approximately 80 nm or less, reliability of the semiconductor device may be degraded due to the increase of the parasitic capacitance.

FIG. 1 is a cross-sectional view illustrating a structure of a typical semiconductor device.

A first inter-layer insulation layer 12 is formed over a substrate 11. Then, a landing plug contact 13 is formed in a contact hole penetrating the first inter-layer insulation layer 12. A second inter-layer insulation layer 14 is formed over the landing plug contact 13 and the first inter-layer insulation layer 12, and a plurality of bit lines BL are formed over predetermined portions of the second inter-layer insulation layer 14. Each of the bit lines BL is formed by sequentially stacking a barrier metal layer 15A, a tungsten layer 15B, and a hard mask nitride layer 15C. A plurality of bit line spacers 16 are formed over sidewalls of the bit lines BL. A third inter-layer insulation layer 17 is formed over an entire surface including the bit lines BL. Then, the third inter-layer insulation layer 17 and the second inter-layer insulation layer 14 are etched to form a storage node contact hole 18 exposing a surface of the landing plug contact 13 between the bit lines BL. A plurality of contact spacers 19 are formed over sidewalls of the storage node contact hole 18. The contact spacers 19 include an insulation material. A storage node contact 20 connected to the landing plug contact 13 fills the storage node contact hole 18.

As described above, since the contact spacers 19 and the bit line spacers 16 include a nitride-based layer, an insulation structure between the bit lines BL and the storage node contact 20 may be a nitride/nitride structure.

The nitride-based layer used as the contact spacers 19 has a k-dielectric constant of approximately 7 or greater and thus, unnecessary parasitic capacitance between the bit lines BL and the storage node contact 20 may be induced.

If an oxide-based layer having a k-dielectric constant lower than the nitride-based layer is used as the contact spacers 19 to reduce the parasitic capacitance, the contact spacers 19 may be damaged to a predetermined thickness during a cleaning process to be employed after performing an etch back process of the contact spacers 19. Accordingly, the contact spacers 19 may not secure a sufficient thickness. Furthermore, in case of reducing a time taken for the cleaning process, an impurity layer such as a native oxide layer may not be completely removed over a landing plug and as a result, contact resistance between the storage node contact 20 and the landing plug contact 13 may be increased.

### SUMMARY OF THE INVENTION

It is, therefore, an object of the present invention to provide a semiconductor device capable of reducing parasitic capacitance between a storage node contact and a bit line caused by a formation of contact spacers, thereby improving reliability of the device, and a method for fabricating the same.

In accordance with one aspect of the present invention, is provided a method for fabricating a semiconductor device, including: forming a plurality of bit lines; forming an inter-layer insulation layer over the bit lines; etching the inter-layer insulation layer to form a storage node contact hole between the bit lines; forming spacers in a dual structure with different dielectric constants over sidewalls of the storage node contact hole; and forming a storage node contact plug filling the storage node contact hole.

In accordance with another aspect of the present invention, there is provided a semiconductor device, including: a plurality of bit lines; a storage node contact formed between the bit lines; and a plurality of spacers between the storage node contact and each of the bit lines, each of the spacers formed in a dual structure with different dielectric constants.

### BRIEF DESCRIPTION OF THE DRAWINGS

The above and other objects and features of the present invention will become better understood with respect to the following description of the exemplary embodiments given in conjunction with the accompanying drawings, in which:

FIG. 1 is a cross-sectional view illustrating a structure of a typical semiconductor device;

FIG. 2 is a cross-sectional view illustrating a semiconductor device in accordance with an embodiment of the present invention;

FIGS. 3A to 3F are cross-sectional views illustrating a method for fabricating a semiconductor device in accordance with another embodiment of the present invention; and

FIG. 4 is a diagram illustrating the insulation structure between the storage node contact and the bit line shown in FIG. 3F.

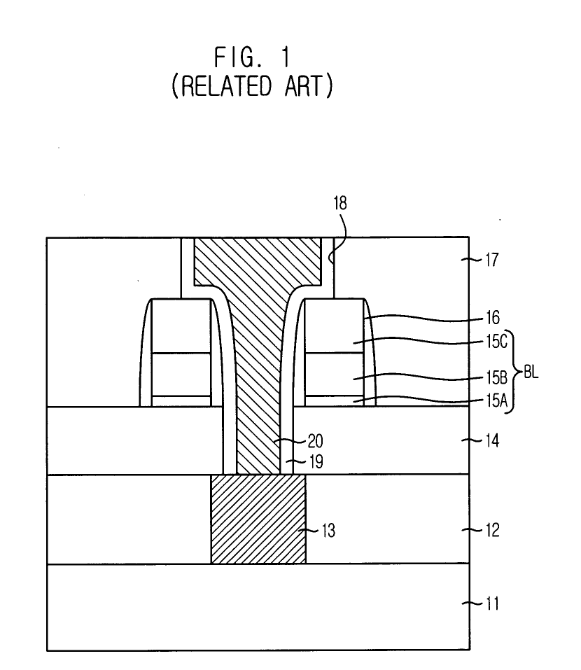

### DETAILED DESCRIPTION OF THE INVENTION

Hereinafter, detailed descriptions on certain embodiments of the present invention will be provided with reference to the accompanying drawings.

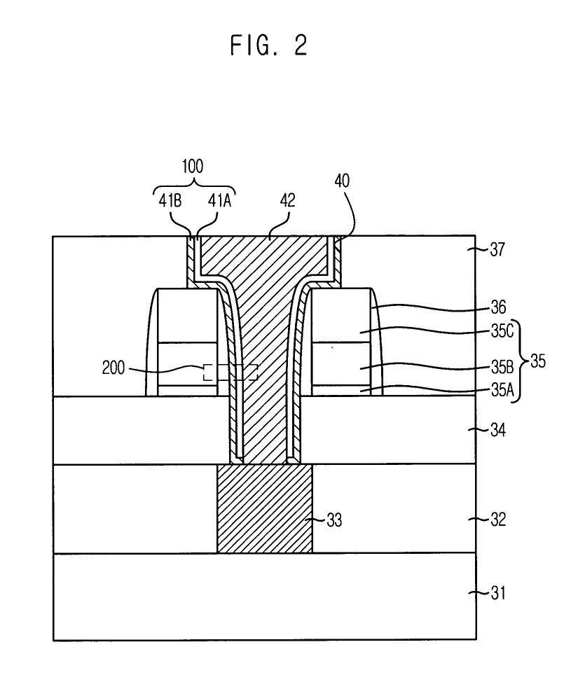

FIG. 2 is a cross-sectional view illustrating a method for fabricating a semiconductor device in accordance with an embodiment of the present invention.

An insulation structure 200 between a bit line 35 and storage node contact 42 is formed with a triple structure of a bit line spacer 36, a nitride-based layer 41B for storage node contact spacers 100, and an oxide-based layer 41A for the storage node contact spacers 100.

In more details, a landing plug contact 33 insulated from neighboring landing plug contacts by a first inter-layer insulation layer 32 is formed over a substrate 31 in which a predetermined process is completed. A second inter-layer insulation layer 34 is formed over the first inter-layer insulation layer 32.

The bit lines 35 disposed apart from each other with a predetermined distance are formed over the second inter-layer insulation layer 34. Each of the bit lines 35 are formed by sequentially stacking a barrier metal layer 35A, a tungsten layer 35B, and a hard mask nitride layer 35C. A plurality of bit line spacers 36 are formed over sidewalls of the bit lines 35.

A third inter-layer insulation layer 37 is formed over the bit lines 35, and a storage node contact hole 40 exposing a surface of the landing plug contact 33 is formed penetrating the third inter-layer insulation layer 37 and the second inter-layer insulation layer 34 between the bit lines 35.

The storage node contact spacers 100, each with a dual structure of the nitride-based layer 41B and the oxide-based layer 41A, are formed over sidewalls of the storage node contact hole 40. The oxide-based layer 41A is formed oxidizing a predetermined portion of an initially formed nitride-based layer for the storage node contact spacers 100 through performing a radical oxidation process. The nitride-based layer 41B is a portion of the initially formed nitride-based layer remaining after performing the radical oxidation process.

Referring to FIG. 2, the insulation structure 200 between the bit line 35 and the storage node contact 42 is formed with the triple structure of the bit line spacer 36, the nitride-based layer 41B, and the oxide-based layer 41A. Since the insulation structure 200 includes the oxide-based layer 41A having a dielectric constant lower than the nitride-based layers, the insulation structure 200 becomes a structure of nitride/nitride/oxide (NNO).

As described above, if the insulation structure 200 formed in the NNO structure exists between the bit line 35 and the storage node contact 42, parasitic capacitance between the bit line 35 and the storage node contact 42 is more reduced compared to the typical insulation structure formed in the nitride/nitride (NN) structure. Specifically, since a dielectric constant of the oxide-based layer 41A of the insulation structure 200 is lower than that of the nitride-based layer, a dielectric constant determining the parasitic capacitance between the bit line 35 and the storage node contact 42 can be decreased. The mathematic equation provides that the capacitance is in proportion to the dielectric constant. Accordingly, the capacitance is reduced as the dielectric constant is reduced.

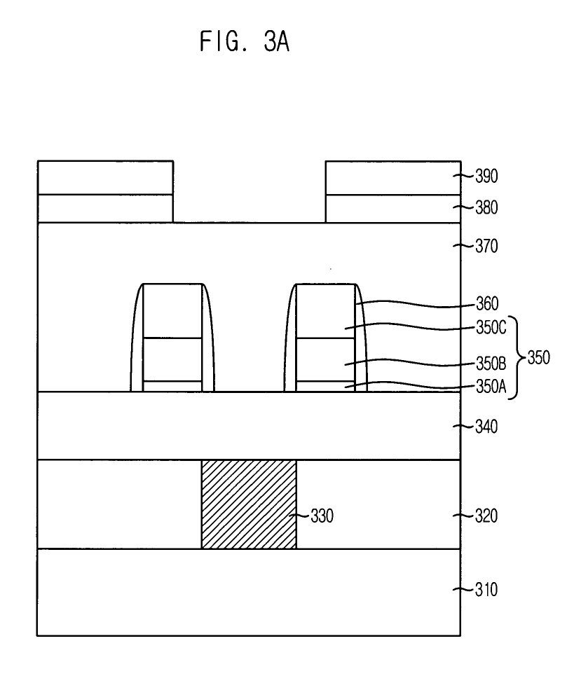

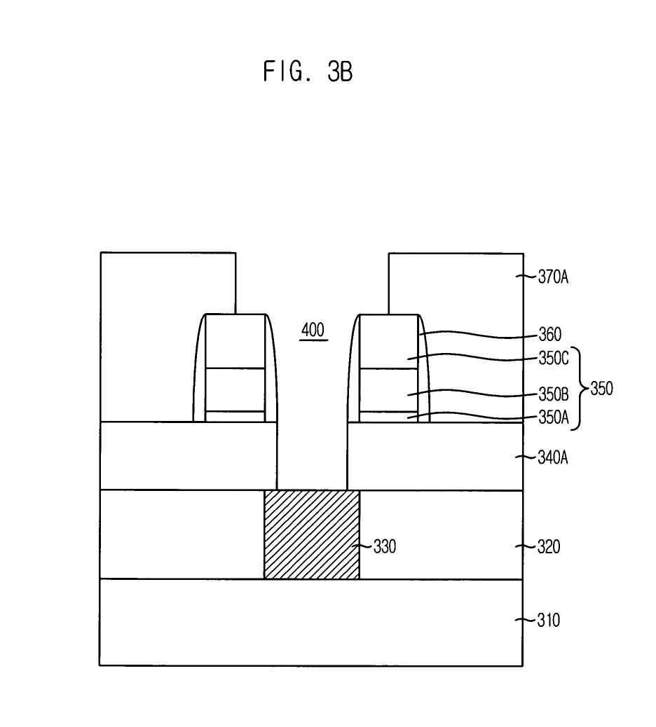

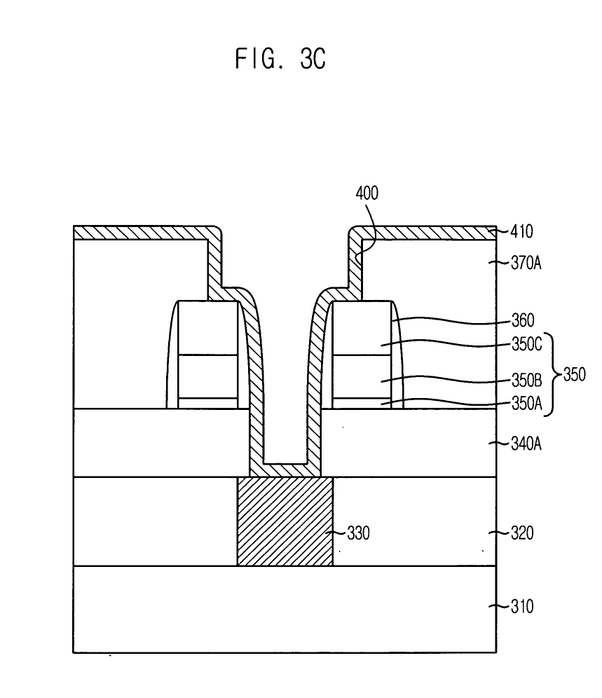

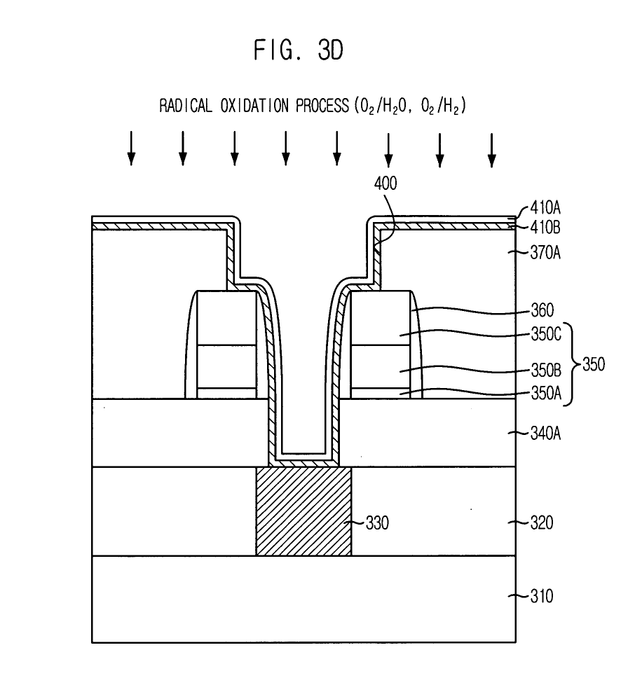

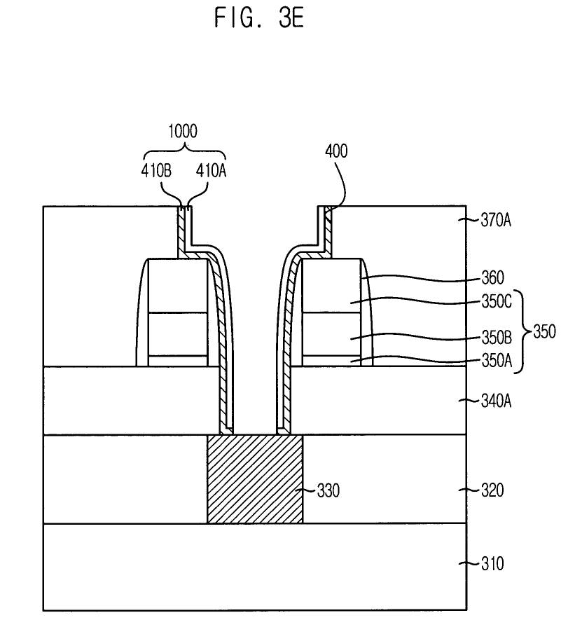

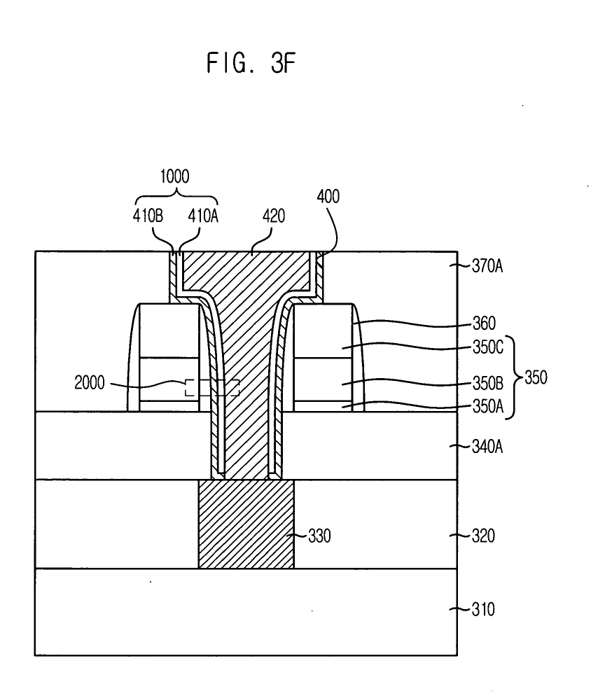

FIGS. 3A to 3F are cross-sectional views illustrating a method for fabricating a semiconductor device in accordance with another embodiment of the present invention.

As shown in FIG. 3A, a first inter-layer insulation layer 320 is formed over a substrate 310 in which a capacitor including a device isolation layer and a gate line (or a word line) is formed. A landing plug contact 330 connected to a predetermined portion of the substrate 310 (i.e., a source/drain region of the capacitor) penetrating the first inter-layer insulation layer 320 is formed. The landing plug contact 330 includes polysilicon.

A second inter-layer insulation layer 340 is formed over the first inter-layer insulation layer 320 including the landing plug contact 330. Then, a plurality of bit lines 350 are formed over predetermined portions of the second inter-layer insulation layer 340. Each of the bit lines 350 is a line pattern formed sequentially stacking a barrier metal layer 350A, a tungsten layer 350B, and a hard mask nitride layer 350C. The barrier metal layer 350A can be formed in a structure of titanium (Ti)/titanium nitride (TiN).

A bit line spacer insulation layer is formed over an entire surface including the bit lines 350 and afterwards, subjected to an etch back process to form a plurality of bit line spacers 360 over sidewalls of the bit lines 350. In more details of the formation of the bit line spacers 360, a silicon nitride layer is formed to a thickness ranging from approximately 100 Å to approximately 250 Å and then, subjected to an etch back process to obtain the bit line spacers 360.

A third inter-layer insulation layer 370 is formed until filing a space between the bit lines 350. The third inter-layer insulation layer 370 includes the same oxide-based layer including a borophosphosilicate glass (BPSG) as the first and second inter-layer insulation layers 320 and 340. A planarization process such as a chemical mechanical polishing (CMP) process can be additionally performed on the third inter-layer insulation layer 370 to reduce a rough surface generated due to a low structure.

A hard mask layer is formed over the third inter-layer insulation layer 370. The hard mask layer is used to overcome insufficient selectivity of an etching process using a subsequent photoresist pattern. The hard mask layer includes polysilicon.

A photoresist layer is formed over the hard mask layer and then, patterned through performing a photo-exposure process and a developing process. As a result, a photoresist pattern 390 serving a role as a storage node contact mask is formed.

The hard mask layer is etched using the photoresist pattern 390 as an etch barrier to obtain a hard mask pattern 380.

As shown in FIG. 3B, a storage node contact etching process using the remaining photoresist pattern 390 and the hard mask pattern 380 as an etch barrier is performed.

In more details, the third inter-layer insulation layer 370 and the second inter-layer insulation layer 340 are etched using the remaining photoresist pattern 390 and the hard mask pattern 380 as the etch barrier to form a storage node contact hole 400 exposing a surface of the landing plug contact 330 between the bit lines 350. As a result, the patterned third inter-layer insulation layer 370A and the patterned second inter-layer insulation layer 340A are obtained. The above etching process can be performed using a self aligned contact (SAC) process. When the storage node contact hole 400 is formed, the remaining photoresist pattern 390 is removed and thus, does not remain.

After the storage node contact hole 400 is formed, the hard mask pattern 380 is removed at the same chamber where the storage node contact etching process is performed. A cleaning process is continuously performed to remove by-products generated during the above etching process.

As shown in FIG. 3C, a first nitride-based layer 410 used as storage node contact spacers is formed over the patterned third inter-layer insulation layer 370A including the storage node contact hole 400. The first nitride-based layer 410 is formed to a thickness ranging from approximately 100 A to approximately 350 A performing one of a low pressure chemical vapor deposition (LPCVD) method and a plasma enhanced chemical vapor deposition (PECVD) method. The first nitride-based layer 410 includes a silicon nitride (Si₃N₄) layer.

As shown in FIG. 3D, after the first nitride-based layer 410 is formed, a radical oxidation process is performed to oxidize a predetermined portion of the first nitride-based layer 410. Due to the radical oxidation process, the predetermined portion of the first nitride-based layer 410 is transformed to an oxide-based layer 410A, and a remaining portion of the first nitride-based layer 410 after performing the radical oxidation process remains as a second nitride-based layer 410B. The oxide-based layer 410A has a SiₓO_{y} structure.

The radical oxidation process performed to form the oxide-based layer 410A implants oxygen (O₂) and hydrogen (H₂) and exerts power to generate plasmas thereto. In more details, either a mixture gas of O₂ and H₂O or another mixture gas of H₂ and O₂ is used at a pressure ranging from approximately 0.3 Torr to approximately 1.5 Torr and a temperature ranging from approximately 400° C. to approximately 700° C. Also, the radical oxidation process comprises using a top radio frequency (RF) power ranging from approximately 3,000 W to approximately 4,000 W, and a side RF power ranging from approximately 300 W to approximately 1,000 W to generate the plasmas. An oxygen radical among the plasmas generated under the above described condition and silicon in the first nitride-based layer 410 can be reacted with each other to form the silicon oxide (SiₓO_{y}) layer. Thus, the oxide-based layer 410A having a thickness corresponding to approximately 30% to approximately 80% of the thickness of the first nitride-based layer 410 is formed, and the reaming portion of the first nitride-based layer 410 is referred to as the second nitride-based layer 410B.

Specifically, the oxygen radical and silicon inside the first nitride-based layer 410 are first reacted from each other to form the SiO₂ layer because a gas having a hydrogen component such as H₂ or H₂O is used. H₂ induces a reduction reaction with the first nitride-based layer 410, and silicon generated by the reduction reaction is reacted with the oxygen radical. As a result, the predetermined portion of the first nitride-based layer 410 is transformed to the SiO₂ layer. The above described oxidation reaction is referred to as a radical oxidation.

The oxide-based layer 410A formed through performing the radical oxidation process has a layer density different from a pure oxide layer formed by performing one of a LPCVD method and a PECVD method. That is, the pure oxide layer formed by performing one of the above deposition methods, and the oxide layer formed by performing the radical oxidation process have different wet etch rates from each other due to a difference in a density of the layer itself.

For instance, the oxide-based layer formed by performing the radical oxidation process has a wet etch rate slower than the pure oxide layer, (e.g., a pure SiO₂ layer) formed by performing the above deposition methods. A wet etch rate of a high density plasma (HDP) oxide layer formed by performing the radical oxidation process is slower than that of the pure oxide layer formed by performing the above deposition methods during a wet etching process.

Damage on the oxide-based layer 410A can be minimized during a subsequent cleaning process due to the slow wet etch rate and thus, sufficient thicknesses of the storage node contact spacers can be maintained.

The oxide-based layer 410A has a dielectric constant of approximately 3.9 which is lower than that of the nitride-based layer, (e.g., the dielectric constant of the nitride-based layer ranges from approximately 7 to approximately 10). Also, the oxide-based layer 410A has a wet etch rate slower than the pure oxide layer. Hence, desirable thicknesses of the storage node contact spacers can be maintained even after a subsequent contact spacer etching process and a subsequent cleaning process are performed. As a result, the parasitic capacitance can be reduced.

As shown in FIG. 3E, the oxide-based layer 410A and the second nitride-based layer 410B are subjected to an etch back process to form a plurality of storage node contact spacers 1000. The storage node contact spacers 1000 are formed over the sidewalls of the storage node contact hole 400 exposing the surface of the landing plug contact 330. Each of the storage node contact spacers 1000 has a dual structure of the oxide-based layer 410A and the second nitride-based layer 410B. Thus, each of the storage node contact spacers 1000 has an enough thickness to prevent an electric short circuit between the tungsten layer 350B of the bit line 350 and a storage node contact plug.

A cleaning process is performed to remove etch by-products using a wet cleaning process. Specifically, a first cleaning process is performed using a mixture solution of H₂SO₄ and H₂O₂ and then, a second cleaning process is performed using a mixture solution of NH₄ and HF.

As shown in FIG. 3F, a conductive layer is formed over the patterned third inter-layer insulation layer 370A until filing the storage node contact hole 400 where the storage node contact spacers 1000 are formed. The conductive layer includes a polysilicon layer. Then, one of an etch back process and a chemical mechanical polishing (CMP) process is performed to planarize the conductive layer until exposing a surface of the patterned third inter-layer insulation layer 370. As a result, a storage node contact 420 is formed.

A reference numeral 2000 indicates the insulation structure between the storage node contact 420 and the tungsten layer 350B of the bit line 350.

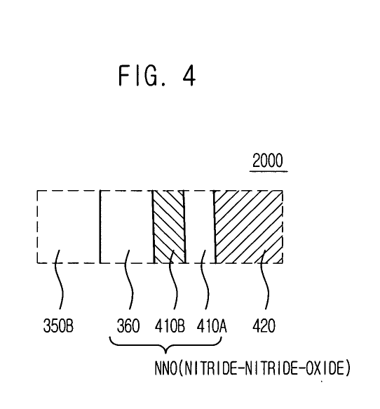

FIG. 4 is a diagram illustrating the insulation structure 2000 to examine capacitance between the storage node contact 420 and the tungsten layer 350B of the bit line3 350 shown in FIG. 3F.

The insulation structure 2000 is formed in a triple structure including the oxide-based layer 410A, the second nitride-based layer 410B, and the bit line spacer 360 between the storage node contact 420 and the tungsten layer 350B of the bit line 350. The bit line spacer 360 includes a nitride-based material. The triple insulation structure 2000 includes the oxide-based layer 410A having a dielectric constant lower than that of the nitride-based layers. Accordingly, the triple structure can be formed in a structure of nitride/nitride/oxide (NNO) in the direction from the tungsten layer 350B of the bit line 350 to the storage node contact 420. Also, the triple structure can be formed in a structure of oxide/nitride/nitride (ONN) in the direction from the storage node contact 420 to the tungsten layer 350B of the bit line 350.

As described above, if the insulation structure 2000 of NNO exists between the tungsten layer 350B of the bit line 350 and the storage node contact 420, the capacitance between the bit line 350 and the storage node contact 420 can be decreased compared to the typical insulation structure of nitride/nitride (NN). Since the oxide-based layer 410A of the NNO structure has a dielectric constant lower than the nitride-based layers, a dielectric constant which practically determines the capacitance between the bit line 350 and the storage node contact 420 can be decreased. According to the mathematic equation calculating the capacitance, the capacitance is in proportion to the dielectric constant. If the dielectric constant is reduced, the capacitance is also reduced accordingly.

An enough thickness to insulate the storage node contact 420 from the bit line 350 can be maintained because of the oxide-based layer 410A capable of minimizing damage on its thickness although a subsequent cleaning process is performed. Accordingly, the capacitance between the storage node contact 420 and the bit line 350 can be more reduced.

For instance, the capacitance C is defined as the following mathematic equation 1.

$$C = ɛ \frac{As}{d} \qquad Eq . 1$$

Herein, ε denotes a dielectric constant; As denotes an effective surface area of an electrode; and d denotes a distance between electrodes. According to the above mathematic equation 1, the capacitance C is in proportion to the dielectric constant ε and the effective surface area As of the electrode, but in inverse proportion to the distance d between the electrodes. To reduce the capacitance C, the dielectric constant ε and the effective surface area As need to be reduced; however, the distance d between the electrodes needs to be increased.

According to this embodiment of the present invention, since the predetermined portion of the initially formed first nitride-based layer 410 (see FIG. 3C) is oxidized through performing the radical oxidation process to form the oxide-based layer 410A, there is an increase in the distance d among the above variables determining the capacitance C. Also, there is a change in the dielectric constant ε because an insulation structure is changed to the triple structure of NNO. However, the effective surface area As is not increased.

Specifically, since the oxide-based layer 410A having the low dielectric constant is disposed in the insulation structure 2000, a total dielectric constant of the insulation structure 2000 between the bit line 350 and the storage node contact 420 can be decreased. However, since the oxide-based layer 410A is formed performing the radical oxidation process, the distance d is increased.

As a result, the capacitance between the bit line 350 and the storage node contact 420 can be reduced forming the insulation structure 2000 of NNO between the bit line 350 and the storage node contact 420.

As described above, when forming the storage node contact spacers 1000 over the sidewalls of the storage node contact hole 400, the first nitride-based layer 410 (see FIG. 3C) is formed as a contact spacer material. Then, the predetermined portion of the first nitride-based layer 410 (see FIG. 3C) is oxidized through performing the radical oxidation process to form the storage node contact spacers 1000. Each of the storage node contact spacers 1000 is formed a dual structure including the oxide-based layer 410A over the second nitride-based layer 410B. Accordingly, the storage node contact spacers 1000 can have a low dielectric constant and an increased distance than spacers including a single nitride-based layer.

Accordingly, the capacitance between the storage node contact 420 and the tungsten layer 350B of the bit line 350 can be reduced.

The oxide-based layer 410A is formed performing the radical oxidation process and thus, damage caused by performing a subsequent cleaning process can be minimized. As a result, it is possible to maintain a thickness of the storage node contact spacers 1000 enough to insulate the storage node contact 420 from the bit line 350.

The storage node contact spacers 1000 having a low dielectric constant and maintaining an enough thickness to insulate the storage node contact 420 from the bit line 350 are formed and as a result, the parasitic capacitance can be reduced. Accordingly, reliability of the device can be improved.

According to this embodiment of the present invention, a nitride-based layer is formed as contact spacers and then, a predetermined portion of the nitride-based layer is oxidized performing a radical oxidation process. As a result, an oxide-based layer having a slower wet etch rate can be obtained. Accordingly, parasitic capacitance can be reduced due to a low dielectric constant of the oxide-based layer and an increased thickness of an insulation layer for an inter-layer insulation.

Also, the above described same effect can be obtained without increasing a thickness of an inter-layer insulation layer, thereby improving a gap-fill margin of the inter-layer insulation layer.

The present application contains subject matter related to the Korean patent application numbers. KR 2006-0016721 and KR 2006-0099886, filed in the Korean Patent Office respectively on Feb. 21, 2006 and Oct. 13, 2006, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a semiconductor device, comprising:
forming a plurality of bit lines;
forming an inter-layer insulation layer over the bit lines;
etching the inter-layer insulation layer to form a storage node contact hole between the bit lines;
forming spacers in a dual structure with different dielectric constants over sidewalls of the storage node contact hole; and
forming a storage node contact plug filling the storage node contact hole.

2. The method of claim 1, wherein the forming of the spacers includes:
forming a first insulation layer over a patterned surface of the inter-layer insulation layer including the storage node contact hole;
transforming a predetermined portion of the first insulation layer to form a second insulation layer having a dielectric constant lower than the first insulation layer;
etching the first and second insulation layers to form the spacers; and
performing a cleaning process to remove by-products after the etching of the first and second insulation layers.

3. The method of claim 2, wherein the first insulation layer comprises a nitride-based layer.

4. The method of claim 3, wherein the second insulation layer comprises an oxide-based layer provided by oxidizing a predetermined portion of the nitride-based layer.

5. The method of claim 4, wherein the oxidizing of the predetermined portion of the nitride-based layer comprises performing a radical oxidation process.

6. The method of claim 5, wherein the radical oxidation process comprises using one of a mixture gas of O₂ and H₂O, and another mixture gas of H₂ and O₂.

7. The method of claim 6, wherein the radical oxidation process is performed at a pressure ranging from approximately 0.3 Torr to approximately 1.5 Torr, and a temperature ranging from approximately 400° C. to approximately 700° C.

8. The method of claim 4, wherein the nitride-based layer is formed to a thickness ranging from approximately 100 Å to approximately 350 Å.

9. The method of claim 8, wherein the oxide-based layer is formed to a thickness corresponding to approximately 30% to approximately 80% of the thickness of the nitride-based layer.

10. The method of claim 9, wherein the cleaning process comprises sequentially performing a first cleaning process using a mixture solution of H₂SO₄ and H₂O₂, and a second cleaning process using a mixture solution of NH₄ and HF.

11. The method of claim 1, wherein each of the bit lines comprises a stack structure including a barrier metal layer, a tungsten layer, and a hard mask nitride layer.

12. The method of claim 11, further comprising bit line spacers formed on sidewalls of the bit lines, wherein the bit line spacers comprising a nitride-based layer.

13. A semiconductor device, comprising:
a plurality of bit lines;
a storage node contact formed between the bit lines; and
a plurality of spacers between the storage node contact and each of the bit lines, each of the spacers formed in a dual structure with different dielectric constants.

14. The semiconductor device of claim 13, wherein each of the spacers formed in the dual structure comprises a first spacer contacting a sidewall of the respective bit line, and a second spacer contacting the storage node contact, wherein the second spacer has a lower dielectric constant than the first spacer.

15. The method of claim 14, wherein the first spacer comprises a nitride-based layer, and the second spacer comprises a material having a dielectric constant lower then the nitride-based layer.

16. The method of claim 15, wherein the second spacer comprises an oxide-based layer formed by oxidizing the nitride-based layer, the nitride-based layer being the first spacer performing a radical oxidation process.

17. The method of claim 16, further comprising a nitride-based spacer between the first spacer and each of the bit line.
